(19) United States
(12) Patent Application Publication
(10) Pub. No.: US 2012/0268901 A1
(43) Pub. Date: Oct. 25, 2012

(54) ELECTRICAL INSTALLATION UNIT

(75) Inventor: Robert Jeschko, Schrems (AT)

(73) Assignee: EATON INDUSTRIES (AUSTRIA) GmbH, Schrems (AT)

(21) Appl. No.: 13/376,288

(22) PCT Filed: Apr. 28, 2010
(86) PCT No.: PCT/AT10/00131

§ 371 Date: Mar. 14, 2012

(30) Foreign Application Priority Data
Jun. 5, 2009 (AT) A874/2009

(51) Int. Cl. H05K 7/14

(52) U.S. Cl. 361/747

(57) ABSTRACT

The invention relates to an electrical installation unit (1) for a surface-type installation, comprising at least one module (2) for wireless data transmission, and further comprising a base plate (3), wherein the installation unit connects the module (2) directly to the base plate (3) in order to reduce the parts that are necessary and to simplify the design.

The invention relates to an electrical installation unit according to the preamble of claim 1.

Electrical installations units for surface-type installation are known which are provided for accommodating a switch or a pushbutton, with the switch or pushbutton comprising a radio transmitter and thereby remote controlling another device, without providing any wire-bound message and/or power connection between the electrical installation unit and the device. Such electrical installation units shall match further components of the home installation arrangement concerning their configuration and their design. An electrical installation unit is known which comprises a base plate for wall mounting of the electrical installation unit, with an intermediate frame being provided on the base plate, and a cover frame is held between the intermediate frame and the base plate. The radio module is held in the intermediate frame, to which the rocker is fastened. The disadvantageous aspect in such a configuration is the high complexity of such a solution.

It is therefore the object of the invention to provide an electrical installation unit of the kind mentioned above with which the mentioned disadvantages can be avoided, with which the number of the required parts can be reduced and with which the configuration can be simplified.

This is achieved in accordance with the invention by the features of claim 1.

The number of the required parts in an electrical installation unit in accordance with the invention can be reduced thereby. Furthermore, the configuration of the same can also be simplified considerably. It is possible to omit a further component or intermediate frame by directly linking or connecting the module with the base plate. The connection can therefore occur without an intermediate frame. As a result, full functionality can be achieved by omitting a component or element, as in the case of known electrical installation units according to the state of the art. In particular, the custom-fit arrangement of different covering or decorative frames on such an electrical installation unit in accordance with the invention is especially also possible. A complex shaped part can be avoided thereby, which is usually arranged as an injection-molded part or as a sheet-steel stamped or bent part and therefore leads to respectively high production costs.

The sub-claims, which like claim 1 simultaneously form a part of the description, relate to further advantageous embodiments of the invention.

The invention will be explained in closer detail by reference to the enclosed drawings in which merely preferred embodiments are shown by way of example, wherein:

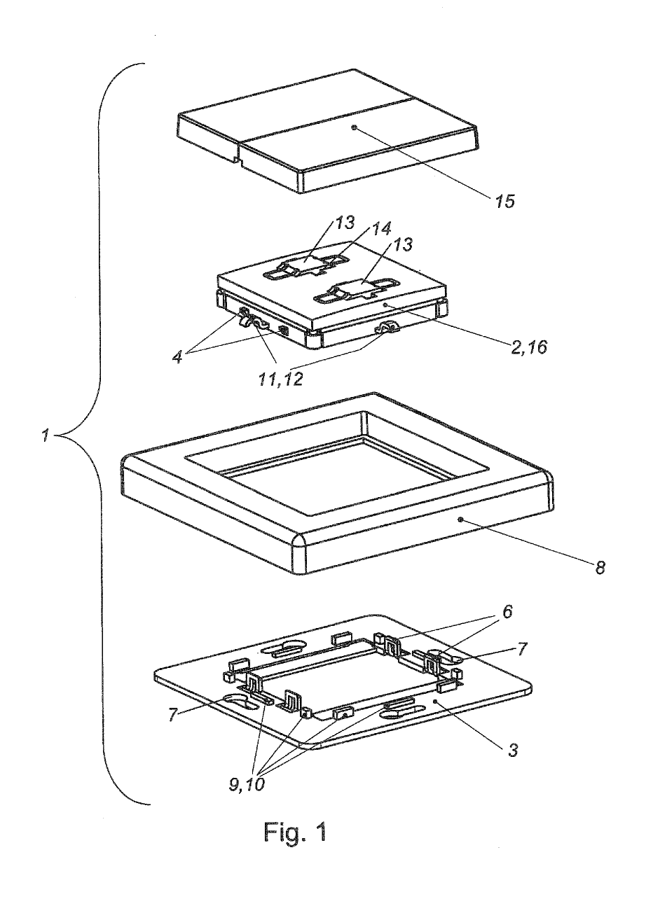

FIG. 1 shows a first especially preferred embodiment of an electrical installation unit in accordance with the invention in an axonometric exploded view, and

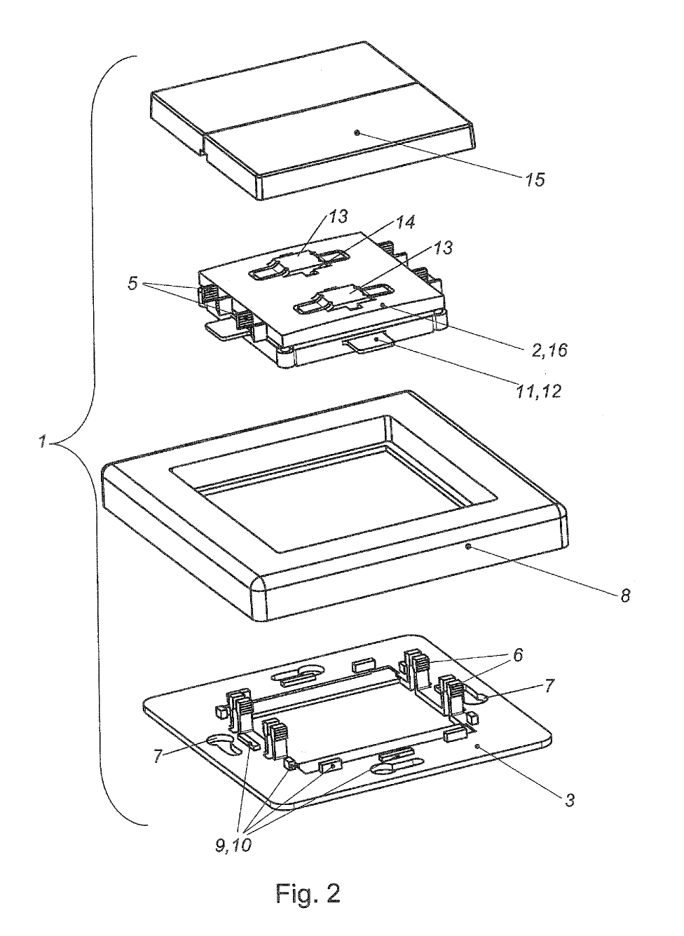

FIG. 2 shows a second especially preferred embodiment of an electrical installation unit in accordance with the invention in an axonometric exploded view.

FIGS. 1 and 2 show an electrical installation unit 1 for surface-type installation, comprising at least one module 2 for wireless data transmission, and further comprising a base plate 3, with the module 2 being directly connected with the base plate 3.

As a result, the number of the required parts in an electrical installation unit 1 in accordance with the invention can be reduced. Furthermore, the configuration of the same can also be simplified considerably. It is possible to omit a further component or intermediate frame by directly linking or connecting the module 2 with the base plate 3. The connection can therefore occur without an intermediate frame. As a result, full functionality can be achieved by omitting a component or element, as in the case of known electrical installation units 1 according to the state of the art. In particular, the custom-fit arrangement of different covering or decorative frames 8 on such an electrical installation unit 1 in accordance with the invention is especially also possible. A complex shaped part can be avoided thereby, which is usually arranged as an injection-molded part or as a sheet-steel stamped or bent part and therefore leads to respectively high production costs.

The electrical installation unit 1 can concern any kind of an electrical installation unit 1 which is provided and/or arranged for so-called surface-type installation, with the term of the surface-type installation comprising the arrangement mounting of the complete electrical installation unit 1 on a substantially flat surface which need not be arranged exclusively as plastered masonry. The term can also relate to an arrangement on a wood and/or a composite panel.

The relevant aspect of the so-called surface-type installation is the fact that no breakthroughs or cavities are required in the surface on which the electrical installation unit 1 is arranged, beneath or behind the electrical installation unit 1, especially no so-called flush-type box.

The electrical installation unit 1 in accordance with the invention preferably concerns an electrical installation unit 1 from the field of home-installation technology, especially respective control devices such as switches and/or pushbuttons which are provided in rooms for controlling substantially electrical consumers such as light switches, buttons and dimmers.

An electrical installation unit 1 in accordance with the invention comprises at least one module 2 for wireless data transmission, which is preferably arranged as a radio module 16, wherein an arrangement as an infrared module or as a module data transmission means of ultrasonic sound can also be provided. The module 2 comprises a module housing which is preferably arranged as an insulating housing. It can be provided that the module 2 or the module housing is arranged to have several parts and may partially also comprise metal parts. It is preferably provided that the module 2 comprises an actuating element 13, especially a pushbutton and/or switch, by means of which the user can enter commands to the module 2. It is provided according to the preferred embodiments as shown in the drawings that the module 2 respectively comprises two actuating elements 13. It is further preferably provided that the module 2 comprises at least one rocker receptacle 14 for a rocker 15, with said rocker receptacle 14 being arranged as an axle in or on the module housing, on which axle a rocker 15 can be inserted.

The electrical installations unit 1 further comprises a base plate 3, which is arranged in a substantially planar or flat manner on the side which is provided for contact with a wall on which the electrical installation unit 1 is to be arranged. The fastening of the electrical installation unit 1 to a wall is preferably provided by means of detachable connection means, which is why preferred embodiments of a base plate 3 comprise at least one receptacle 7 such as holes for connection means for surface-type installation. It can be provided that the electrical installation unit 1 is fastened to a wall by means of an adhesive such as a double-sided adhesive tape. It is preferably provided in this case that the flat side of the base plate 3 comprises sufficiently large contiguous areas in order to ensure secure contact between the base plate 3 and the adhesive.

It is provided in accordance with the invention that the module 2 is directly connected with the base plate 3, such that the connection between the module 2 and the base plate 3 is free from further components. A part of the module 2 or the module housing is therefore directly connected with a part of the base plate 3, or rests on the same.

Different types of the connection of the module 2 and the base plate 3 can be provided. It can be provided for example that the module 2 is screwed together with the base plate 3. It is especially preferably provided however that the module 2 is directly connected with the base plate 3 by means of a plug-in and/or snap-in connection, by means of which an especially simple and rapidly implementable connection can be achieved between the module 2 and the base plate 3. It is possible to omit further connecting elements. It is provided in accordance with the embodiment in FIG. 1 that the module 2 comprises at least one snap-in lug 4 which engages into snap-lock seats 6 of the base plate 3, with the snap-in lugs 4 preferably being arranged as projections with a triangular lateral cross-section. It is provided in accordance with FIG. 2 that the module 2 comprises at least one snap-in rib 5 which engages in snap-lock seats 6 of the base plate 3, with the snap-in ribs 5 preferably being arranged in pairs as is illustrated and comprising a predeterminable number of snap-in projections on the respectively facing areas, which snap in projections are arranged for engagement in respectively diametrically opposed snap-lock seats 6 of the base plate 3, which snap-lock seats are arranged in pairs. This arrangement offers the special advantage that the snap-in ribs 5 and the snap-lock seats 6 of the base plate 3 are accessible from the front to the fitter after removing the rockers 15 and a module 2 can be separated in a simple and destruction-free manner from the base plate 3 by compressing the snap-lock seats 6 which are arranged in pairs. It can also be provided that contrary to the embodiments shown in the drawings the base plate 3 comprises at least one snap-in nose and/or snap-in rib which engages in snap-lock seats of the module 2.

As already explained above, the present invention allows arranging different cover frames 8 which can also be designated as decorative or ornamental frames on an electrical installation unit 1 in accordance with the invention, with no further intermediate frame or other components being required. It is therefore provided according to the especially preferred embodiments of the invention that at least one cover frame 8 is arranged between the base plate 3 and the module 2, by means of which the electrical installation unit 1 can be adjusted to the design or the configuration of the further home installation. It is preferably provided that the cover frame 8 is directly held on the base plate 3 by the module 2, by means of which it is possible to omit further fastening means such as screws or the like. In order to ensure precise positioning of the cover frame 8 and to thereby ensure small gaps and precise gap dimensions between the cover frames 8 and the rocker 15, it is preferably provided that for positioning the cover frame 8, positioning elements 9 are arranged on the base plate 3, which positioning elements 9 are preferably arranged as stops 10, as shown for example in FIG. 1 and FIG. 2.

It is preferably provided for directly holding the cover frame 8 on the base plate 3 merely by way of the module 2 that the module 2 comprises at least one retainer 11 in order to hold the cover frame 8 on the base plate 3, especially in order to press the cover frame 8 against the base plate 3. It is preferably provided that the at least one retainer 11 is arranged as a projection 12 of the housing, as is shown in FIG. 1 and FIG. 2. It is especially preferably provided that as shown in FIG. 1 the projection 12 of the housing is arranged as a resilient projection 12 of the housing. A predeterminable force can thereby be exerted on the cover frame 8, by means of which it is held in an especially secure manner on the base plate 3.

FIGS. 1 and 2 respectively show an especially preferred embodiment of an electrical installation unit in accordance with the invention in an axonometric exploded view, with the illustration of the individual parts occurring in the sequence of the intended assembly of the individual parts. The cover frame 8 is placed on the base plate 3 which is fastened to the wall, whereupon the module 2 is connected with the base plate 3, by means of which the cover frame 8 is also held, and thereafter the rockers 15 are placed on the module 2.

Further embodiments in accordance with the invention merely have a part of the described features, wherein any combination of features can be provided, especially also of different described embodiments.

1.-13. (canceled)

14. An electrical installation unit for surface-type installation, comprising:
a base plate;
at least one module for wireless data transmission, said module being directly connected with the base plate; and
at least one cover frame arranged between the base plate and the module.

15. The electrical installation unit of claim 14, wherein the module is connected to the base plate in the absence of any further components.

16. The electrical installation unit of claim 14, wherein the module is directly connected to the base plate by a plug-in and/or snap-in connection.

17. The electrical installation unit of claim 14, wherein the module comprises at least one snap-in lug and/or snap-in rib to engage in a snap-lock seat of the base plate.

18. The electrical installation unit of claim 14, wherein the base plate comprises at least one snap-in lug and/or snap-in rib to engage in a snap-lock seat of the base plate.

19. The electrical installation unit of claim 14, wherein the base plate comprises at least one receiver for a connector for surface-type installation.

20. The electrical installation unit of claim 14, wherein the cover frame is held on the base plate directly by the module.

21. The electrical installation unit of claim 14, further comprising positioning elements arranged on the base plate for positioning the cover frame.

22. The electrical installation unit of claim 21, wherein the positioning elements are configured as stops.

23. The electrical installation unit of claim 14, wherein the module comprises at least one retainer to hold the cover frame on the base plate.

24. The electrical installation unit of claim 23, wherein the retainer is constructed to press the cover frame against the base plate.

25. The electrical installation unit of claim 23, wherein the retainer is configured as a resilient housing projection.

26. The electrical installation unit of claim 14, wherein the module comprises an actuating element.

27. The electrical installation unit of claim 26, wherein the actuator is configured as a pushbutton and/or switch.

28. The electrical installation unit of claim 14, wherein the module comprises at least one rocker receiver for a rocker.

29. The electrical installation unit of claim 14, wherein the module is configured as a radio module.
